(19) United States
(12) Patent Application Publication
(10) Pub. No.: US 2022/0103120 A1
(43) Pub. Date: Mar. 31, 2022

(54) LIGHT-CONCENTRATING SOLAR DEVICE

(71) Applicants: Xiaoping Hu, Shenzhen, Guangdong (CN); BOLYMEDIA HOLDINGS CO. LTD., Santa Clara, CA (US)

(72) Inventor: Xiaoping Hu, Shenzhen, Guangdong (CN)

(21) Appl. No.: 17/421,015

(22) PCT Filed: Jan. 30, 2019
(86) PCT No.: PCT/CN2019/073965

§ 371 Date: Jul. 6, 2021

(51) Int. Cl. H02S 40/22

(52) U.S. Cl. CPC H02S 40/22

(57) ABSTRACT

Disclosed is a light-concentrating solar device, comprising two nested reflection-type light-concentrating troughs, and a double-sided light energy utilization device. The direction of a top opening of the second light-concentrating trough is consistent with the direction of a top opening of the first light-concentrating trough, and the bottom of the second light-concentrating trough is located inside the first light-concentrating trough. The double-sided light energy utilization device is arranged at the bottom of the second light-concentrating trough, and both the front and back sides of the double-sided light energy utilization device can receive sunlight, with one of the sides facing the top of the second light-concentrating trough, and the other side facing the bottom of the first light-concentrating trough. The above structure can achieve a higher light-concentrating efficiency.

### TECHNICAL FIELD

The present disclosure relates to clean energy, in particular to reflective light-concentrating solar devices.

### BACKGROUND OF THE INVENTION

Solar energy systems have been widely used with the increasing demands for clean energy; in this respect, reflective light-concentrating solar devices using reflecting surfaces to concentrate light become particularly valued due to low cost.

However, the concentrating ratio of the reflective light-concentrating solar devices is usually low. Therefore, it is necessary to study a reflection-type light-concentrating solar device that can improve the concentrating ratio while maintaining low cost.

### SUMMARY OF THE INVENTION

In accordance with the present disclosure, a light-concentrating solar device disclosed may include two nested light-concentrating troughs and a double-sided light energy utilization apparatus. A first light-concentrating trough may include a side wall and a bottom wall, wherein the side wall may define a top having a larger opening and a base having a smaller opening, the base may be closed by the bottom wall, and the inner surfaces of the side wall and the bottom wall may be at least partially reflecting surfaces. A second light-concentrating trough may include a side wall which defines a top having a larger opening and a base having a smaller opening, wherein the inner surface of the side wall may be at least partially a reflecting surface. The opening direction of the top of the second light-concentrating trough may be consistent with the opening direction of the top of the first light-concentrating trough; and the bottom of the second light-concentrating trough may be arranged inside the first light-concentrating trough and spaced apart from the bottom of the first light-concentrating trough. The double-sided light energy utilization apparatus may be arranged at the bottom of the second light-concentrating trough, the front and back sides thereof may be able to receive sunlight with one side facing toward the top of the second light-concentrating trough and the other side facing toward the bottom of the first light-concentrating trough.

The light-concentrating solar device according to the present disclosure can achieve a higher concentration ratio by means of adopting two nested light-concentrating troughs, and the light converged by the first light-concentrating trough and the second light-concentrating trough can be received by one side of the double-sided light energy utilization apparatus, significantly improving the efficiency of light energy utilization.

The light-concentrating solar device according to the present disclosure can be installed horizontally (that is, the opening of the light-concentrating trough is upward), or it can be installed upright (that is, the opening of the light-concentrating trough is facing the side; in this respect, the wall of the trough is preferably asymmetrical) to adapt to different installation requirements.

Specific examples according to the present disclosure are described in detail below with reference to the accompanying drawings. As used herein, the serial numbers or sequence numbers used herein, such as “first”, “second”, etc., are merely illustrative without any restrictive meanings. Terms that indicate a position, such as “upper”, “lower”, “front”, “rear”, “obverse”, “reverse”, “side”, “top”, “bottom” and the like, only refer to relative positional relationships, having no absolute meanings.

### BRIEF DESCRIPTION OF THE DRAWINGS

FIG. 1 is a schematic diagram of a light-concentrating solar device according to a first embodiment;

FIG. 2 is a schematic diagram of a light-concentrating solar device according to a second embodiment;

FIG. 3 is a schematic diagram of a light-concentrating solar device according to a third embodiment;

FIG. 4 is a schematic diagram of a light-concentrating solar device according to a fourth embodiment;

### DETAILED DESCRIPTION

### Embodiment 1

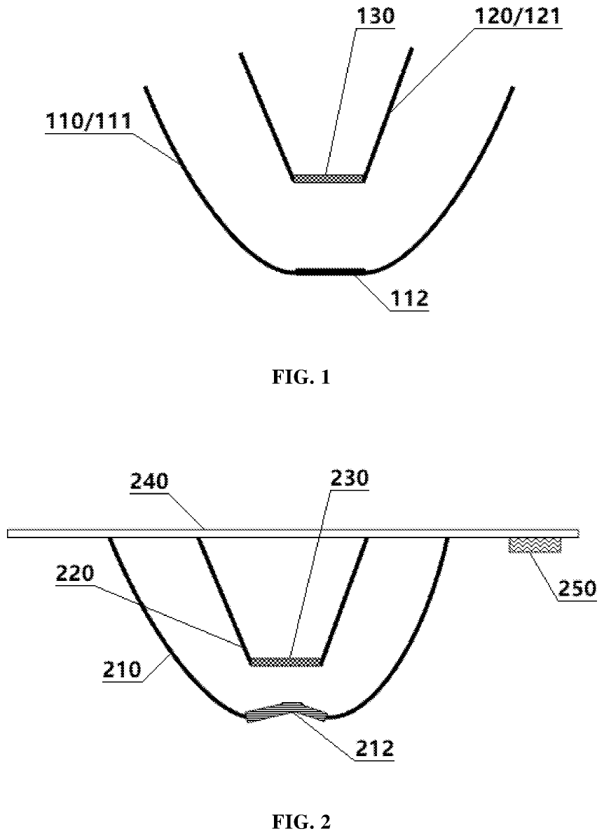

Referring to FIG. 1, a light-concentrating solar device according to a first embodiment of the present disclosure may include a first light-concentrating trough 110, a second light-concentrating trough 120 and a double-sided light energy utilization apparatus 130.

The first light-concentrating trough 110 may include a side wall 111 and a bottom wall 112. The side wall may define a top having a larger opening and a base having a smaller opening. The base is closed by the bottom wall 112. The inner surfaces of the side wall and the bottom wall may at least partially be reflecting surfaces, or all of them may be reflecting surfaces.

The second light-concentrating trough 120 may include a side wall 121 defining a top having a larger opening and a base having a smaller opening. The inner surface of the side wall may at least partially be a reflecting surface, or it may be a reflecting surface. In other embodiments, the outer surface of the side wall of the second light-concentrating trough may also be a reflecting surface so that it may be coordinated with the first light-concentrating trough to reflect light.

FIG. 1 shows a cross-sectional view of the device of this embodiment along the incident direction of sunlight. The device may be of different three-dimensional structures. For example, the first light-concentrating trough and the second light-concentrating trough can be strip-type grooves extending in the length direction; in this respect, the side walls thereof may usually be served by two planar or curved surfaces oppositely arranged, and the two ends of the strip-type grooves can be enclosed or unenclosed. Alternatively, the side walls of the first and second light-concentrating troughs may also be formed as enclosed folded surfaces or curved surfaces, for example, they may be formed as a conical surface or a rectangular cone surface.

The opening direction of the top of the second light-concentrating trough 120 (that is, the incident direction of sunlight) is the same as the opening direction of the top of the first light-concentrating trough 110. The bottom of the second light-concentrating trough is arranged inside the first light-concentrating trough and is spaced apart from the bottom of the first light-concentrating trough. In this embodiment, the second light-concentrating trough 120 is only partially contained in the first light-concentrating trough. In other embodiments, the second light-concentrating trough may also be fully contained in the first light-concentrating trough; specifically, the top of the second light-concentrating trough may be flush with the top of the first light-concentrating trough.

The double-sided light energy utilization apparatus 130 is arranged at the bottom of the second light-concentrating trough 120, and its front and back sides can receive sunlight, wherein one side faces toward the top of the second light-concentrating trough, and the other side faces toward the bottom of the first light-concentrating trough.

The double-sided light energy utilization apparatus in this embodiment adopts a double-sided photosensitive light energy utilization apparatus, such as a double-sided photovoltaic wafer. In other embodiments, a photothermal utilization apparatus or a comprehensive photoelectric and photothermal utilization apparatus may also be used, for example, a photothermal conversion apparatus that can be heated on both sides, or a mixing arrangement with photovoltaic panels on one side and a heat transfer medium on the other side.

The device according to this embodiment can be manufactured at a lower cost by means of adopting reflecting surface(s) to converge light, and the arrangement of the two nested light-concentrating trough coordinated with the double-sided light energy utilization apparatus can greatly improve the efficiency of light energy utilization and reduces the loss of light reflection.

### Embodiment 2

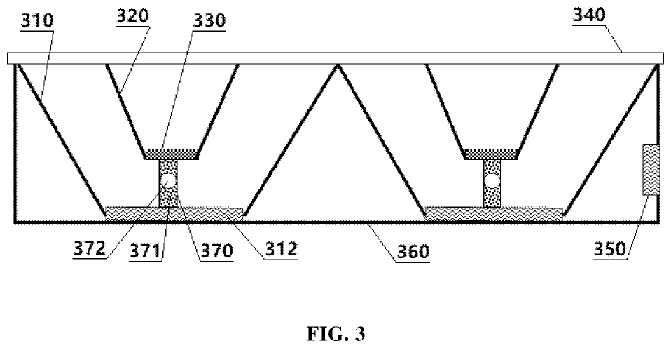

Referring to FIG. 2, a light-concentrating solar device according to a second embodiment of the present disclosure may include a first light-concentrating trough 210, a second light-concentrating trough 220 and a double-sided light energy utilization apparatus 230.

The differences between this embodiment and Embodiment 1 lie in:

1. The bottom wall 212 of the first light-concentrating trough 210 is not flat; instead, it is formed as a convex reflective surface with the direction in which it protrudes facing toward the top of the first light-concentrating trough. In other embodiments, the bottom wall of the first light-concentrating trough may also be formed as a reflection-type Fresnel lens (that is, a Fresnel lens with a mirror coating on its back side). Such Fresnel lens may include a reflection-type linear Fresnel lens. The so-called “linear Fresnel lens” may mean that the focal center of the lens is not a point but a line.

2. The second light-concentrating trough 220 is received in the first light-concentrating trough 210.

3. In addition, as a preferred embodiment, the device of this embodiment may further include a top cover 240 and a piezoelectric vibrating piece 250.

The top cover 240, at least partially transparent or all transparent, may close the top of the first light-concentrating trough 210. Obviously, since the second light-concentrating trough 220 is contained in the first light-concentrating trough 210, the top cover 240 may also enclose the top of the second light-concentrating trough 220. The first light-concentrating trough and the top cover together form a closed container, so that the reflecting surface and the double-sided light energy utilization apparatus inside the device can be protected from dust. In other embodiments, a special frame can also be provided to seal the entire light-concentrating solar device.

The piezoelectric vibrating piece 250, which can be made of piezoelectric ceramics, is fixedly connected to the top cover 240, and cleans the top cover 240 through vibration, such as shaking off dust or foreign objects on the top cover.

### Embodiment 3

Referring to FIG. 3, a light-concentrating solar device in a third embodiment according to the present disclosure is shown. The figure shows an integrated arrangement in which a plurality of units can be integrated together (arranged in an array, for example). Each unit may include a first light-concentrating trough 310, a second light-concentrating trough 320, and a double-sided light energy utilization apparatus 330. In addition, the top cover 340 and piezoelectric vibrating piece 350 are shared by the entire integrated arrangement.

In addition to such integrated structure, the differences between this embodiment and Embodiment 2 are as follows:

1. The bottom wall 312 of the first light-concentrating trough 310 is flat and formed as a reflection-type Fresnel lens.

2. An additional frame 360 is used to enclose the entire integrated arrangement, and the piezoelectric vibrating piece 350 is fixed on the frame 360 instead of the top cover 340. In other embodiments, the first light-concentrating trough and the second light-concentrating trough may also be formed as part of the frame.

3. Moreover, as a preferred embodiment, the device of this embodiment may further include a heat-conducting support 370 which is arranged between the double-sided light energy utilization apparatus 330 and the bottom wall 312 of the first light-concentrating trough 310 for conducting heat generated by the double-sided light energy utilization apparatus away. For example, the heat-conducting support 370 may be of a hollow structure with a reflecting surface as the outer surface thereof, and a heat storage medium 371 filled inside. The inside of the support is provided with a thermal energy utilization apparatus 372 to absorb and utilize the heat generated by the double-sided light energy utilization apparatus 330. The thermal energy utilization device can be a pipe for heat exchange with the outside, or a thermoelectric conversion apparatus.

### Embodiment 4

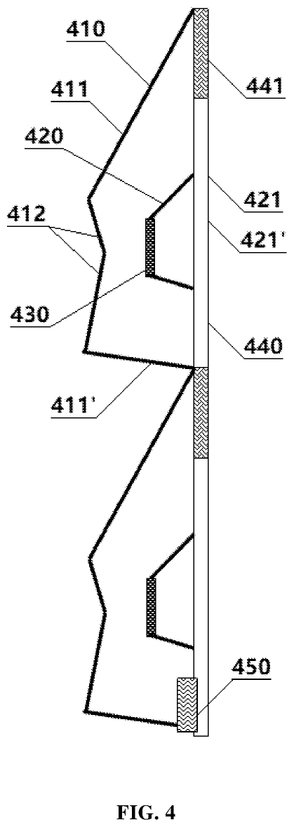

Referring to FIG. 4, a light-concentrating solar device in a fourth embodiment according to the present disclosure is shown. The figure shows an arrangement for vertical installation which may include a plurality of units integrated together. Each unit may include a first light-concentrating trough 410, a second light-concentrating trough 420, a double-sided light energy utilization apparatus 430 and a top cover 440. In addition, the piezoelectric vibrating piece 350 may be shared by the entire integrated arrangement.

In addition to such integrated structure, the difference between this embodiment and Embodiment 2 lies in that:

1. The entire arrangement is installed vertically, so the sunlight will only deflect in one direction, which also leads to the structural difference described in item 2 below.

2. The side walls 411, 411′ of the first light-concentrating trough 410 are asymmetrical, and the side walls 421, 421′ of the second light-concentrating trough 420 are also asymmetrical. With regard to vertical installation, it means that the side walls are asymmetric in the vertical direction. In this respect, for strip-type grooves, this means that the two oppositely arranged planar or curved surfaces formed as the side walls are asymmetrical. As to the enclosed side walls, this means that the enclosed folded surfaces or curved surfaces are asymmetric in the vertical direction. Furthermore, in addition to the side walls being asymmetrical, the bottom wall 412 of the first light-concentrating trough 410 may also be asymmetrical.

3. At least part of the top cover 440 is formed as a Fresnel lens 441 so as to obtain a higher concentration ratio.

By means of adopting vertical installation and equipping with piezoelectric vibrating piece, the device of this embodiment is excellent in dust proof, snow proof and ice proof, and can be used as a solar wall.

The principle and implementation manners of the present disclosure has been described above with reference to specific embodiments, which are merely provided for the purpose of understanding the present disclosure and should not be construed as limiting the present disclosure. It will be possible for those skilled in the art to make variations based on the idea of the present disclosure.

1. A light-concentrating solar device, comprising:
a first light-concentrating trough including a side wall and a bottom wall, the side wall defining a top having a larger opening and a base having a smaller opening, the base being closed by the bottom wall, and the inner surfaces of the side wall and the bottom wall being at least partially reflecting surfaces, wherein the bottom wall of the first light-concentrating trough is formed as a convex reflective surface with a direction in which it protrudes facing toward the top of the first light-concentrating trough;
a second light-concentrating trough including a side wall, the side wall defining a top having a larger opening and a base having a smaller opening, the inner surface of the side wall being at least partially a reflecting surface, the opening direction of the top of the second light-concentrating trough being consistent with the opening direction of the top of the first light-concentrating trough, and the bottom of the second light-concentrating trough being arranged inside the first light-concentrating trough and spaced apart from the bottom of the first light-concentrating trough; and
a double-sided light energy utilization apparatus arranged at the bottom of the second light-concentrating trough, the front and back sides thereof being able to receive sunlight with one side facing toward the top of the second light-concentrating trough and the other side facing toward the bottom of the first light-concentrating trough.

2. The light-concentrating solar device according to claim 1,
further comprising a top cover which is at least partially transparent;
the second light-concentrating trough being received inside the first light-concentrating trough, and the top of the first light-concentrating trough being enclosed by the top cover.

3. The light-concentrating solar device according to claim 2,
wherein at least a part of the top cover is formed as a Fresnel lens.

4. The light-concentrating solar device according to claim 1,
wherein the side wall of the first or second light-concentrating trough includes two planar surfaces or curved surfaces arranged oppositely.

5. The light-concentrating solar device according to claim 4,
wherein the two planar surfaces or curved surfaces arranged oppositely are asymmetrical.

6. The light-concentrating solar device according to claim 1,
wherein the side wall of the first or second light-concentrating trough is formed as an enclosed folded surface or curved surface.

7. The light-concentrating solar device according to claim 6,
wherein the enclosed folded surface or curved surface is asymmetrical.

8. (canceled)

9. The light-concentrating solar device according to claim 1,
further comprising a heat-conducting support arranged between the double-sided light energy utilization apparatus and the bottom wall of the first light-concentrating trough and configured for conducting away heat energy generated by the double-sided light energy utilization apparatus.

10. The light-concentrating solar device according to claim 1,
wherein the double-sided light energy utilization apparatus is a double-sided photovoltaic wafer, or a photothermal utilization apparatus, or a comprehensive photoelectric and photothermal utilization apparatus.

11. The light-concentrating solar device according to claim 2,
further comprising a closed frame, the first light-concentrating trough and the second light-concentrating trough being enclosed in the frame or formed as a part of the frame.

12. The light-concentrating solar device according to claim 11,
further comprising a piezoelectric vibrating piece fixedly connected to the top cover or the frame.
